(19) United States
(12) Patent Application Publication
(10) Pub. No.: US 2023/0298948 A1
(43) Pub. Date: Sep. 21, 2023

(54) TEMPERATURE MEASUREMENT METHOD, SEMICONDUCTOR SUBSTRATE, AND SEMICONDUCTOR DEVICE

(71) Applicant: Kioxia Corporation, Tokyo (JP)

(72) Inventor: Naoki KOSAKA, Yokkaichi (JP)

(73) Assignee: Kioxia Corporation, Tokyo (JP)

(21) Appl. No.: 17/930,541

(22) Filed: Sep. 8, 2022

(30) Foreign Application Priority Data
Mar. 18, 2022 (JP) 2022-043438

(51) Int. Cl. H01L 21/66; G01K 11/125; G01K 11/14; H01L 27/11582

(52) U.S. Cl. CPC H01L 22/20; G01K 11/125; G01K 11/14; H01L 27/11582; H01L 22/30; H01L 21/31116

(57) ABSTRACT

A temperature measurement method according to one embodiment includes a step of applying measurement light having a predetermined wavelength to a reflective film formed on a first surface of a substrate. Furthermore, the temperature measurement method includes a step of receiving, with an optical member, reflected light generated by the measurement light being reflected by the reflective film. Furthermore, the temperature measurement method includes a step of calculating the temperature of the substrate based on a reflectance based on the ratio between the intensity of the measurement light and the intensity of the reflected light.

### CROSS-REFERENCE TO RELATED APPLICATIONS

This application is based upon and claims the benefit of priority from Japanese Patent Application No. 2022-043438, filed on Mar. 18, 2022; the entire contents of which are incorporated herein by reference.

### FIELD

An embodiment described herein relates generally to a temperature measurement method, a semiconductor substrate, and a semiconductor device.

### BACKGROUND

In a manufacturing process of a semiconductor device and the like, a technique of measuring a temperature of a substrate to be subjected to plasma processing and the like in a non-contact manner is used.

### BRIEF DESCRIPTION OF THE DRAWINGS

FIG. 1 is a side cross-sectional view illustrating one example of the configuration of a semiconductor manufacturing device according to an embodiment;

FIG. 2 is a cross-sectional view illustrating one example of the configuration of a substrate according to the embodiment;

FIG. 3 is a cross-sectional view illustrating one example of a state near a lift pin at the time of temperature measurement using the substrate according to the embodiment;

FIG. 4 is a bottom view of the substrate W illustrating a first example of the shape of a reflective film according to the embodiment;

FIG. 5 is a bottom view of the substrate W illustrating a second example of the shape of the reflective film according to the embodiment;

FIG. 6 is a bottom view of the substrate W illustrating a third example of the shape of the reflective film according to the embodiment;

FIG. 7 is a flowchart illustrating one example of steps in a temperature measurement method according to the embodiment; and

FIG. 8 is a cross-sectional view illustrating one example of the configuration of a three-dimensional memory serving as a semiconductor device according to the embodiment.

### DETAILED DESCRIPTION

According to one embodiment, a temperature measurement method is provided. The temperature measurement method includes a step of applying measurement light having a predetermined wavelength to a reflective film formed on a first surface of a substrate.

Furthermore, the temperature measurement method includes a step of receiving, with an optical member, reflected light generated by the measurement light being reflected by the reflective film. Furthermore, the temperature measurement method includes a step of calculating the temperature of the substrate based on a reflectance based on the ratio between the intensity of the measurement light and the intensity of the reflected light.

Hereinafter, a temperature measurement method, a substrate, and a semiconductor device according to the embodiment will be described below with reference to the accompanying drawings. Note that the present invention is not limited by the following embodiment. Furthermore, components in the following embodiment include those that can be easily assumed by those skilled in the art or those that are substantially the same.

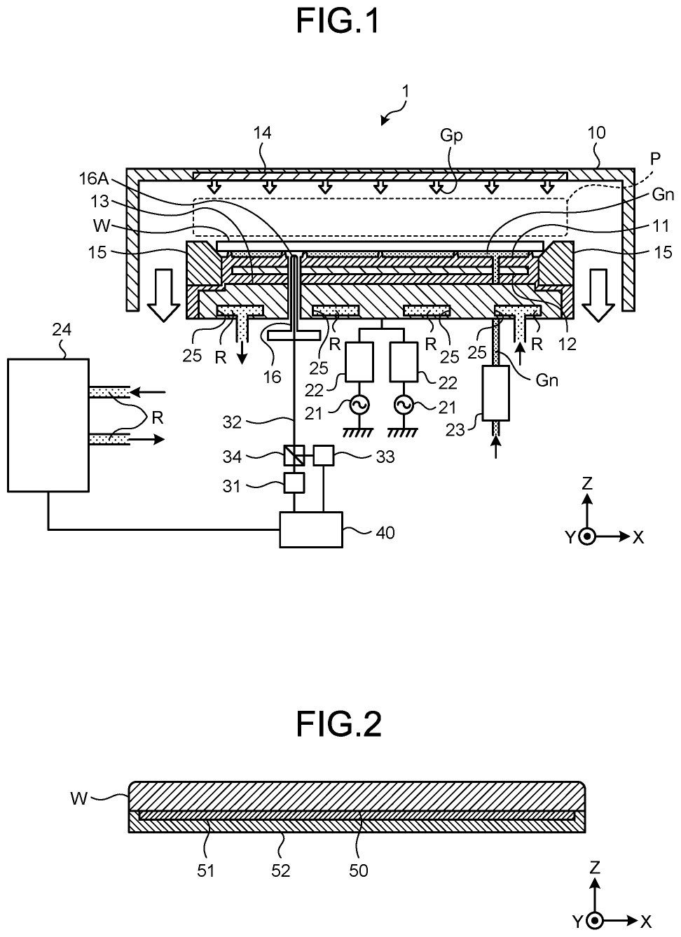

FIG. 1 is a side cross-sectional view illustrating one example of the configuration of a semiconductor manufacturing device 1 according to the embodiment. An X axis corresponds to the horizontal direction of the paper surface. A Y axis corresponds to the front-back direction of the paper surface. A Z axis corresponds to the vertical direction of the paper surface.

The semiconductor manufacturing device 1 according to the embodiment can generate plasma P in a chamber 10, and perform plasma processing on the surface of a substrate W. The substrate W can be, for example, a semiconductor wafer such as a silicon wafer. Note, however, that the substrate W is not limited to the semiconductor wafer, and may be, for example, a quartz substrate. The plasma processing can be, for example, dry etching and cryoetching on a film to be processed formed on the front surface of the substrate W. The cryoetching is dry etching performed in a low temperature environment. The low temperature environment is, for example, an environment of 0° C. or less, more specifically of −40° C. or less. Furthermore, the semiconductor manufacturing device 1 according to the embodiment has a function of measuring the temperature of the substrate W by using a phenomenon in which the reflectance of light reflected by a certain object changes in accordance with the temperature of the object.

The semiconductor manufacturing device 1 includes a mounting table 11, an electrostatic chuck electrode 12, a radio frequency (RF) electrode 13, a ground electrode 14, a focus ring 15, a lift pin 16 (one example of movable member), a radio frequency power source 21, a matching circuit 22, a gas flow rate control device 23, a chiller 24, a light source 31, an optical fiber 32 (one example of optical member), a detector 33, a half mirror 34, and an arithmetic device 40.

The mounting table 11 is a member on which the substrate W to be processed is mounted, and is made of a conductive material. The gas flow rate control device 23 supplies rare gas Gn such as He to space between the mounting table 11 and the substrate W.

The electrostatic chuck electrode 12 is provided inside the mounting table 11, and generates a magnetic force for bonding, by pressure, the substrate W to the mounting table 11 by being supplied with a voltage. The focus ring 15 is a member provided so as to surround the outer periphery of the substrate W mounted on the mounting table 11, and has an effect of preventing diffusion of the plasma P in the outer edge of the substrate W and stabilizing processing on the portion.

The RF electrode 13 is disposed below the mounting table 11, and is connected to the radio frequency power source 21 via the matching circuit 22. The matching circuit 22 matches impedance between the radio frequency power source 21 and a load (e.g., RF electrode 13). The ground electrode 14 maintains a predetermined ground potential, and is disposed so as to face the RF electrode 13. The ground electrode 14 is installed above the RF electrode 13 (mounting table 11) (in this example, in vicinity of upper wall surface of chamber 10), and has a plurality of holes through which process gas Gp can be supplied into the chamber 10. The supply of the process gas Gp is controlled by an appropriate gas supply device. The plasma P is generated between the substrate W and the ground electrode 14 by supplying a radio frequency voltage to the RF electrode 13 with the radio frequency power source 21 in a state where the chamber 10 is filled with the process gas Gp. Furthermore, the chamber 10 includes a mechanism that discharges internal air to the outside.

The lift pin 16 is a rod-like member extending in the vertical direction (direction parallel to Z axis), and is vertically displaced by predetermined power. When the lift pin 16 is displaced upward, an end 16A of the lift pin 16 abuts on the substrate W, and pushes up the substrate W. When the substrate W is mounted (fixed) on the mounting table 11, the lift pin 16 is displaced such that the end 16A of the lift pin 16 is located below the substrate W. Note that, although FIG. 1 illustrates only one lift pin 16, a plurality of (at least three) lift pins 16 is provided so that the substrate W can be raised and lowered while being maintained in a horizontal state.

The optical fiber 32 is installed inside the lift pin 16. The optical fiber 32 is installed in the extending direction of the lift pin 16, applies measurement light output from the light source 31 from the end 16A of the lift pin 16 toward the substrate W, and causes reflected light from the substrate W to be incident on the detector 33. The light source 31 outputs measurement light. When a reflective film 51 to be described later contains Al, the wavelength of the measurement light is preferably around 780 nm. The half mirror 34 is disposed between the light source 31 and the lower end of the optical fiber 32, transmits light traveling from below to above, and reflects (refracts) the light traveling from above to below. The action of the half mirror 34 causes the measurement light output from the light source 31 to be emitted from an upper end of the optical fiber 32 (end 16A of lift pin 16), and causes the reflected light incident from the upper end of the optical fiber 32 to be incident on the detector 33. The detector 33 is a device capable of measuring intensity (radiation flux) of light, and measures the intensity of reflected light from the substrate W (reflective film 51 to be described later).

The arithmetic device 40 is an information processing device including, for example, a processor that performs arithmetic processing in accordance with a program, and executes processing for calculating the temperature of the substrate W. The arithmetic device 40 calculates the reflectance of reflected light generated by measurement light being reflected by the substrate W (reflective film 51 to be described later) based on information acquired from the detector 33, and calculates the temperature of the substrate W based on the reflectance. The reflectance is a value based on the ratio between the intensity of measurement light emitted from the light source 31 and the intensity of reflected light incident on the detector 33. For example, when the reflectance is defined as Re, the intensity of the measurement light is defined as I1, and the intensity of the reflected light is defined as I2, the reflectance can be calculated by Re=I2/I1. The temperature of the substrate W can be calculated by using, for example, a table that is stored in a memory and indicates the relation between the reflectance and the temperature.

A refrigerant flow path 25 for circulating a refrigerant R is formed inside the RF electrode 13. The refrigerant flow path 25 is connected to the chiller 24. The chiller 24 controls the flow rate and temperature of the refrigerant R such that the difference between the temperature of the substrate W and a predetermined set temperature is reduced based on the temperature of the substrate W calculated by the arithmetic device 40.

FIG. 2 is a cross-sectional view illustrating one example of the configuration of the substrate W according to the embodiment. The reflective film 51 and a protective film 52 are formed on a back surface 50 of the substrate W according to the embodiment. Note that, in the description of the semiconductor manufacturing device 1 in FIG. 1, the reflective film 51 and the protective film 52 are not illustrated.

When the temperature of the substrate W is measured, measurement light emitted from the upper end of the optical fiber 32 is applied to the reflective film 51. The reflective film 51 has characteristics suitable for reflecting measurement light. The reflectance of the reflective film 51 to the measurement light is higher than the reflectance of the back surface 50 of the substrate W to the measurement light. Although a material constituting the reflective film 51 can be appropriately selected in accordance with a use situation, the material preferably includes at least one of, for example, aluminum (Al), molybdenum (Mo), titanium nitride (TiN), platinum (Pt) and gold (Au). The material constituting the reflective film 51 may be selected based on, for example, film formability, thermal conductivity, and a rate of change in reflectance to temperature change in addition to being capable of reflecting measurement light with a reflectance higher than that of the back surface 50 of the substrate W. For example, it is preferable to use a material that satisfies conditions such as a sufficiently large change rate of reflectance to temperature change in a temperature range (e.g., −40° C. or less) to be measured, good film formability of the substrate W to the back surface 50, and sufficiently high thermal conductivity. For example, when measurement light of 780 to 900 nm is applied, AI of the reflective film 51 has a large change in reflectance between 120 Kelvin (K) and 370K. Similarly, when measurement light of around 780 nm is applied, TiN of the reflective film 51 has a large change in reflectance. When Mo or Pt is used as the reflective film 51, measurement light of 780 nm is useful, for example. When Au is used as the reflective film 51, measurement light of 532 nm is useful, for example.

The protective film 52 has a property of transmitting measurement light and reflected light, and covers the reflective film 51. Although a material constituting the protective film 52 can be appropriately selected in accordance with a use situation, the material preferably includes at least one of, for example, SiN and SiO from the viewpoint of translucency, film formability, hardness, and the like. The protective film 52 can inhibit chipping of the reflective film 51 and the back surface 50 of the substrate W and contamination in the chamber 10 due to peeling of the reflective film 51, for example. Note that the protective film 52 is not necessarily required to be formed, and may be omitted in accordance with a use situation.

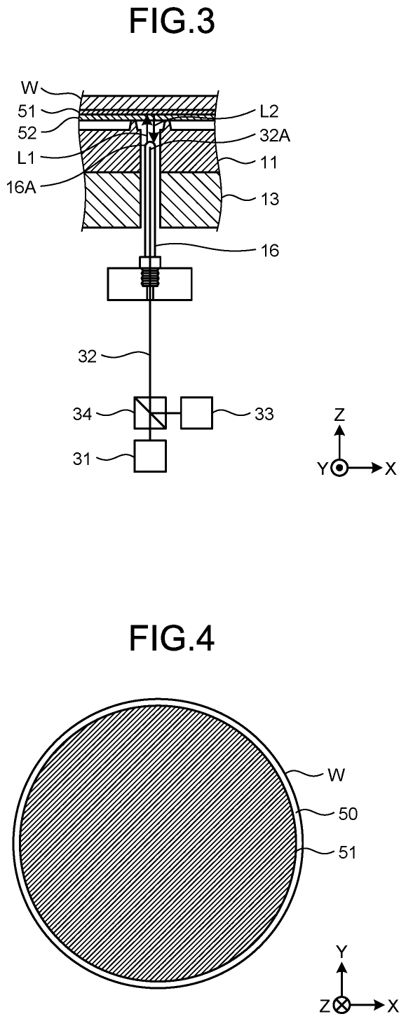

FIG. 3 is a cross-sectional view illustrating one example of a state near the lift pin 16 at the time of temperature measurement using the substrate W according to the embodiment. At the time of temperature measurement, measurement light L1 output from the light source 31 passes through the optical fiber 32 disposed inside the lift pin 16, and is emitted from an upper end 32A of the optical fiber 32 located at the end 16A of the lift pin 16. An emission direction of the measurement light L1 is adjusted so as to be perpendicular or substantially perpendicular to the back surface 50 of the substrate W mounted on the mounting table 11. Reflected light L2 is generated by the measurement light L1 being reflected by the reflective film 51 formed on the back surface 50 of the substrate W. The reflected light L2 is received by the upper end 32A of the optical fiber 32, and is incident on the detector 33 through the optical fiber 32.

As described above, the reflected light L2 can be detected more stable than in a case where the measurement light L1 is directly applied to the back surface 50 of the substrate W by the measurement light L1 being applied to the reflective film 51. This allows improvement of calculation accuracy of reflectance, and thus improvement of calculation accuracy of the temperature of the substrate W.

In order to transmit and receive the measurement light L1 and the reflected light L2 as described above, the position of the lift pin 16 and the position of the reflective film 51 need to match with each other. FIGS. 4 to 6 illustrate variations of the shape of the reflective film 51. Note that, in FIGS. 4 to 6, the description of the protective film 52 is omitted.

FIG. 4 is a bottom view of the substrate W illustrating a first example of the shape of the reflective film 51 according to the embodiment. The reflective film 51 of the example is formed over substantially the entire region except for the vicinity of the outer edge of the back surface 50 of the substrate W. The reflective film 51 having such a shape eliminates the need for alignment processing of aligning the position of the lift pin 16 and the position of the reflective film 51 at the time of temperature measurement.

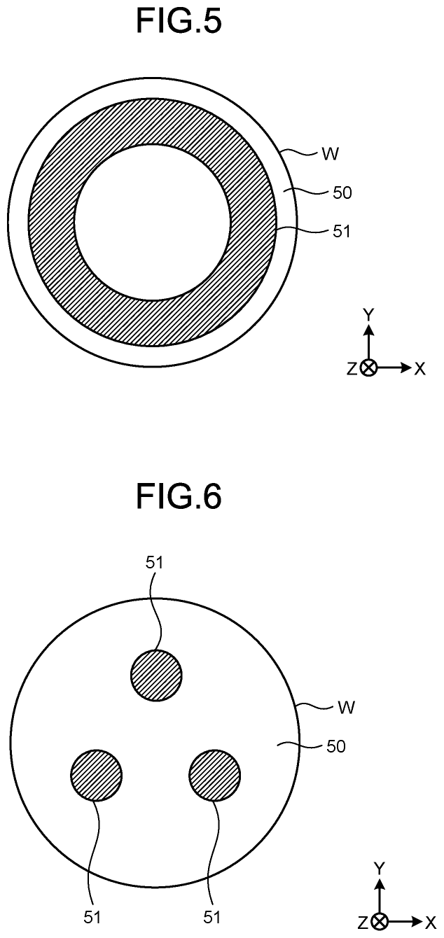

FIG. 5 is a bottom view of the substrate W illustrating a second example of the shape of the reflective film 51 according to the embodiment. FIG. 6 is a bottom view of the substrate W illustrating a third example of the shape of the reflective film 51 according to the embodiment. The reflective film 51 of the second example in FIG. 5 includes an annular portion. The reflective film 51 of the third example in FIG. 6 includes a plurality of (three in the example) portions arranged to be separated from each other. Any of the reflective films 51 of the second example and the third example is formed only in a portion corresponding to the position of the lift pin 16. The reflective film 51 having such a shape causes the need for alignment processing at the time of temperature measurement, but can reduce costs of forming the reflective film 51.

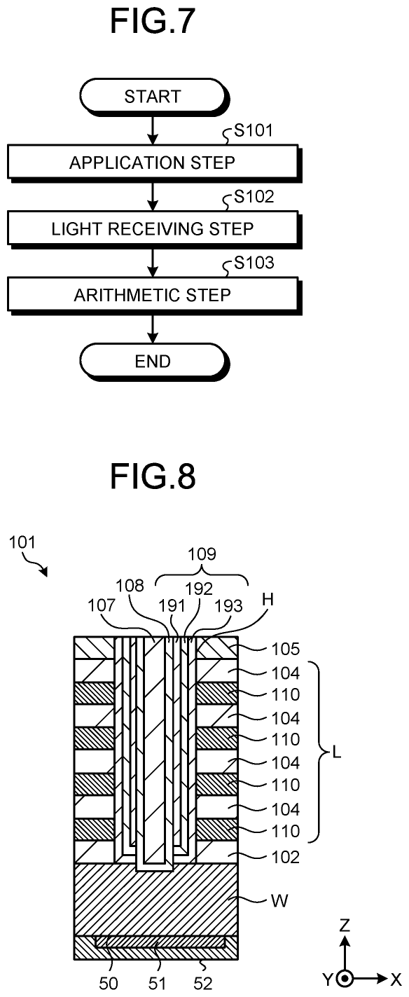

FIG. 7 is a flowchart illustrating one example of steps in the temperature measurement method according to the embodiment. After the substrate W is mounted and fixed on the mounting table 11, an application step (S101) and a light receiving step (S102) are performed. In the application step, the measurement light L1 is applied from the upper end 32A of the optical fiber 32 to the reflective film 51 formed on the back surface 50 of the substrate W. In the light receiving step, the reflected light L2 from the reflective film 51 is received at the upper end 32A of the optical fiber 32. Then, an arithmetic step (S103) is performed. In the arithmetic step, a reflectance based on the ratio between the intensity of the measurement light L1 and the intensity of the reflected light L2 is calculated, and the temperature of the substrate W is calculated based on the reflectance. Note that, before S101, a step of preliminarily determining a wavelength region having a large change in reflectance due to temperature may be performed on reflective film 51.

According to the above-described method, the reflectance can be calculated with high accuracy based on the stable reflected light L2, and thus the temperature of the substrate W can be calculated with high accuracy.

Measurement of the temperature of the substrate W by the method as described above is preferably executed before the plasma processing or the cryoetching processing is executed on the surface of the substrate W, for example. Alternatively, the measurement may be performed in the middle of or after execution of the processing.

The temperature measurement method as described above can be used in manufacturing processes of various semiconductor devices. The temperature measurement method according to the embodiment can be used in a manufacturing process of a three-dimensional memory (one example of semiconductor device) in which a plurality of memory cells is three-dimensionally formed on the front surface of the substrate W, for example. For example, in a method of manufacturing a semiconductor device using the temperature measurement method according to the embodiment, first, the substrate W in FIG. 2 is prepared, and a film to be processed is formed on the front surface of the substrate W. Then, the temperature of the substrate W is measured by the temperature measurement method according to the embodiment, and the film to be processed is processed to form a device layer on the front surface of the substrate W. Then, the semiconductor device is manufactured through a post-step and the like. Note that the semiconductor device is not limited to the three-dimensional memory.

FIG. 8 is a cross-sectional view illustrating one example of the configuration of a three-dimensional memory 101 serving as the semiconductor device according to the embodiment. The three-dimensional memory 101 includes the substrate W, a base layer 102, a stacked body L, a conductive layer 105, a core insulating layer 107, a semiconductor channel layer 108, and a memory layer 109.

The base layer 102 includes an insulating film containing, for example, silicon oxide and silicon nitride. The stacked body L includes a plurality of stacked unit layers including an electrode layer 110 and an insulating layer 104. The insulating layer 104 contains, for example, silicon oxide. The conductive layer 105 is formed on the stacked body L, and includes, for example, a carbon film. A plurality of memory holes H is formed in the stacked body L and the conductive layer 105. Although FIG. 8 illustrates only one memory hole H, actually, a plurality of memory holes H is formed. The core insulating layer 107, the semiconductor channel layer 108, and the memory layer 109 are formed in each of the memory holes H. The core insulating layer 107 contains silicon oxide and the like. The semiconductor channel layer 108 and the memory layer 109 contains polysilicon and the like.

The memory layer 109 includes a tunnel insulating layer 191, a charge storage layer 192, and a block insulating layer 193. The tunnel insulating layer 191 includes a stacked body including, for example, a silicon oxide film and a silicon oxynitride film. The charge storage layer 192 includes, for example, silicon nitride. The block insulating layer 193 contains, for example, silicon oxide. The memory layer 109 constitutes a plurality of memory cells. Each memory cell is formed for each unit layer of the stacked body L.

In the manufacture of the semiconductor device in FIG. 8, for example, the temperature measurement method according to the embodiment can be used in the step of forming the memory hole H in the stacked body serving as a film to be processed. The stacked body in the step of forming the memory hole H is obtained by alternately stacking the insulating layer 104 and a sacrificial layer (not illustrated), for example. After the core insulating layer 107, the semiconductor channel layer 108, and the memory layer 109 are formed in the memory hole H, the sacrificial layer is replaced with the electrode layer 110.

As described above, the reflective film 51 and the protective film 52 are formed on the back surface 50 of the substrate W used for manufacturing the three-dimensional memory 101 according to the embodiment. Note that the protective film 52 is not required to be formed. As described above, such a substrate W allows management of the temperature of the substrate W with high accuracy. For example, in the step of forming the memory hole H in FIG. 8, the gas flow rate control device 23 and the chiller 24 are controlled based on the temperature of the substrate W obtained by the temperature measurement method according to the embodiment to change thermal conductivity of gas or change the temperature of the refrigerant R supplied from the chiller 24. More specifically, an optimum temperature of the substrate W and a wavelength for processing are stored in advance in the storage unit (memory or the like) of the semiconductor manufacturing apparatus 1.

Thereafter, the reflective film 51 is irradiated with the measurement light during the step of forming the memory holes H, and the temperature is calculated by a detection unit. Thereafter, the detected temperature is fed back to the chiller 24, and a controller (not illustrated) controls the chiller 24 if it is not within the desired temperature range. The temperature of the substrate W at the time of cryoetching processing can thereby be optimized. For example, an etching rate can be increased by processing the substrate W at a lower temperature. The shape and size of a hole can be finely adjusted by processing the substrate W at a higher temperature (ordinary temperature). This allows manufacture of the three-dimensional memory 101 with high quality.

Note that, although a case where the semiconductor manufacturing device is a plasma processing device has been described in the above-described embodiment, the semiconductor manufacturing device is not limited to the plasma processing device. Furthermore, the temperature measurement method according to the embodiment can be used not only for a semiconductor manufacturing device but for various devices and systems including a configuration capable of applying measurement light and receiving reflected light.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

(Supplement)

The contents of the above-described embodiment will be supplemented below.

(Supplement 1)

A method of manufacturing a semiconductor device that:
applies measurement light having a predetermined wavelength to a reflective film formed on a first surface of a substrate;
receives, with the optical member, reflected light generated by the measurement light being reflected by the reflective film; and
calculating temperature of the substrate based on reflectance based on a ratio between intensity of the measurement light and intensity of the reflected light.

What is claimed is:

1. A temperature measurement method comprising:
applying measurement light having a predetermined wavelength to a reflective film formed on a first surface of a substrate;
receiving, with an optical member, reflected light generated by the measurement light being reflected by the reflective film; and
calculating temperature of the substrate based on reflectance based on a ratio between intensity of the measurement light and intensity of the reflected light.

2. The temperature measurement method according to claim 1,
wherein the reflective film is covered with a protective film capable of transmitting the measurement light.

3. The temperature measurement method according to claim 1,
wherein the reflective film includes at least one of Al, Mo, TiN, Pt and Au.

4. The temperature measurement method according to claim 2,
wherein the protective film includes at least one of SiN and SiO.

5. The temperature measurement method according to claim 1,
wherein the temperature is calculated before plasma processing is executed on a surface opposite to the first surface of the substrate.

6. The temperature measurement method according to claim 1,
wherein the temperature is calculated before cryoetching is executed on a surface opposite to the first surface of the substrate.

7. The temperature measurement method according to claim 1,
wherein a temperature range to be measured is 0° C. or less.

8. The temperature measurement method according to claim 1,
wherein the wavelength is 780 nm or more and 900 nm or less.

9. A semiconductor substrate,
wherein a reflective film and a protective film are formed on a first surface, the reflective film including at least one of Al, Mo, TiN, Pt and Au, the protective film covering the reflective film and having an exposed surface, and
a surface opposite to the first surface is exposed.

10. The semiconductor substrate according to claim 9,
wherein the protective film includes at least one of SiN and SiO.

11. The semiconductor substrate according to claim 10,
wherein the reflective film includes an annular portion.

12. The semiconductor substrate according to claim 10,
wherein the reflective film includes a plurality of portions arranged to be separated from each other.

13. A semiconductor device comprising:
a substrate;
a reflective film including at least one of Al, Mo, and TiN provided on a first surface of the substrate;
a protective film that covers the reflective film and has an exposed surface; and
a device layer provided on a surface opposite to the first surface of the substrate.

14. The semiconductor device according to claim 13,
wherein the protective film includes at least one of SiN and SiO.

15. The semiconductor device according to claim 13,
wherein the device layer includes: a stacked body in which a plurality of unit layers including an electrode layer and an insulating layer is stacked; and a plurality of memory holes formed on the stacked body.
